(19) United States
(12) Patent Application Publication
(10) Pub. No.: US 2026/0282912 A1
(43) Pub. Date: Sep. 17, 2026

(54) SEMICONDUCTOR DEVICE

(71) Applicant: HITACHI ASTEMO, LTD., Hitachinaka-shi, Ibaraki (JP)

(72) Inventors: Nayuta YAMACHI, Hitachinaka-shi, Ibaraki (JP); Ayumu HATANAKA, Hitachinaka-shi, Ibaraki (JP); Masahiro UETAKE, Hitachinaka-shi, Ibaraki (JP); Takeshi SEKI, Hitachinaka-shi, Ibaraki (JP); Akihiko NOIE, Hitachinaka-shi, Ibaraki (JP)

(73) Assignee: HITACHI ASTEMO, LTD., Hitachinaka-shi, Ibaraki (JP)

(21) Appl. No.: 18/872,895

(22) PCT Filed: Jun. 22, 2022
(86) PCT No.: PCT/JP2022/024982

§ 371 Date: Dec. 9, 2024

(51) Int. Cl. H10W 40/47; H02K 11/33

(52) U.S. Cl. CPC H10W 40/47; H02K 11/33

(57) ABSTRACT

A semiconductor device includes a power module, a first housing and a second housing respectively having adhesion surfaces, the adhesion surfaces adhering to each other to provide a refrigerant channel, and a seal material. One of the adhesion surfaces of the first housing and the second housing includes a seal material application portion to which the seal material is applied, the other adhesion surface includes a seal material pressing portion against which the seal material is pressed, the seal material pressing portion being provided at a position corresponding to the seal material application portion, and one of the adhesion surfaces of the first housing and the second housing includes a seal material inflow suppression portion that suppresses an inflow of the seal material into the refrigerant channel, the seal material inflow suppression portion being provided at a position closer to the refrigerant channel than the seal material application portion.

### TECHNICAL FIELD

The present invention relates to a semiconductor device.

### BACKGROUND ART

A cooling channel for cooling a semiconductor device is formed by joining housings, but high reliability is required for assembly of the housings during the forming of the cooling channel.

For example, PTL 1 below discloses a power conversion device, on a joint portion between the housings, having a structure with a double groove on a surface to which a seal material is applied and a configuration where a protrusion is provided.

### CITATION LIST

### Patent Literature

PTL 1: JP 2016-92209 A

### SUMMARY OF INVENTION

### Technical Problem

In the structure of PTL 1, although sealing itself has no problem, the degradation of assembly might be caused by corrosion when the seal material comes into contact with a refrigerant channel. In view of this, an object of the present invention is to provide a semiconductor device where prevention of decrease in adhesive strength is compatible with prevention of inflow of an adhesive into a refrigerant channel.

### Solution to Problem

A semiconductor device includes a power module that outputs electric power for driving a motor using a semiconductor, a first housing and a second housing respectively having adhesion surfaces, the adhesion surfaces adhering to each other to provide a refrigerant channel for cooling the power module, and a seal material that seals the adhesion surfaces of the first housing and the second housing. One of the adhesion surfaces of the first housing and the second housing includes a seal material application portion to which the seal material is applied, the other adhesion surface includes a seal material pressing portion against which the seal material is pressed, the seal material pressing portion being provided at a position corresponding to the seal material application portion, and one of the adhesion surfaces of the first housing and the second housing includes a seal material inflow suppression portion that suppresses an inflow of the seal material into the refrigerant channel, the seal material inflow suppression portion being provided at a position closer to the refrigerant channel than the seal material application portion.

### Advantageous Effects of Invention

According to the present invention, it is possible to provide a semiconductor device where prevention of decrease in adhesive strength is compatible with prevention of inflow of an adhesive into a refrigerant channel.

### BRIEF DESCRIPTION OF DRAWINGS

FIG. 1 is an assembled perspective view of a power conversion device.

FIG. 2 is a cross-sectional view taken along line A-A of the power conversion device of FIG. 1 according to one embodiment of the present invention.

FIG. 3 is an explanatory view of adhesion portions of housings of FIG. 2 according to one embodiment of the present invention.

FIG. 4 is an explanatory view of a relationship between a seal material and the adhesion surfaces according to one embodiment of the present invention.

FIG. 5 illustrates shape patterns of a pressing portion and an application portion.

FIG. 6 illustrates first to fourth modifications of the pressing portion, the application portion, and a storage portion.

FIG. 7 illustrates fifth and sixth modifications of the pressing portion, the application portion, and the storage portion.

### DESCRIPTION OF EMBODIMENTS

Hereinafter, an embodiment of the present invention will be described with reference to the drawings. The following description and drawings are examples for describing the present invention, and are omitted and simplified as appropriate for the sake of clarity of the description. The present invention can be carried out in various other modes. As for each component, unless otherwise specified, single component or a plurality of components may be provided.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the positions, sizes, shapes, ranges, and the like disclosed in the drawings.

### One Embodiment and Overall Device Configuration of Present Invention

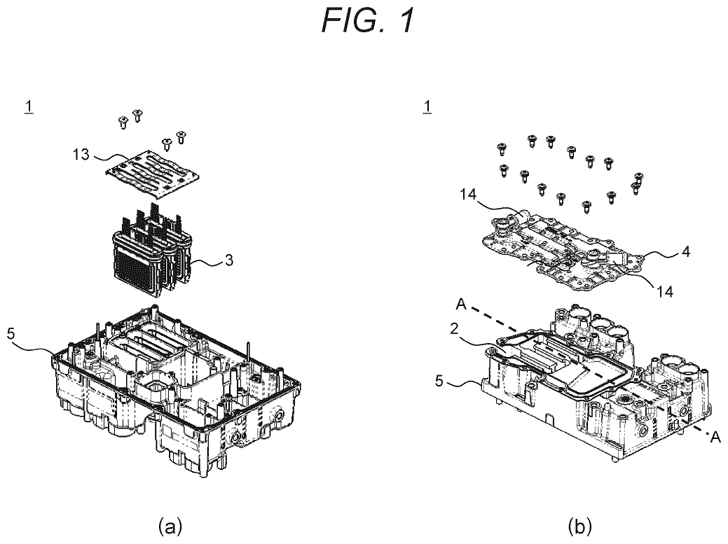

### FIG. 1

FIG. 1(a) is an explanatory view of a power module housed in a housing, and FIG. 1(b) is an explanatory view of a lower cover attached to the housing. In a semiconductor device 1, a power module 3 that outputs electric power for driving a motor using a semiconductor is inserted into a case 5, and a power module plate 13 is assembled to the case 5 to house and hold the power module 3 in a sandwiched manner.

A lower cover 4 includes a water passage pipe 14. The water passage pipe 14 is press-fitted into the lower cover 4. A seal material (described later) is applied to a groove of the case 5, and the lower cover 4 is assembled to the case 5 with them sandwiching the seal material.

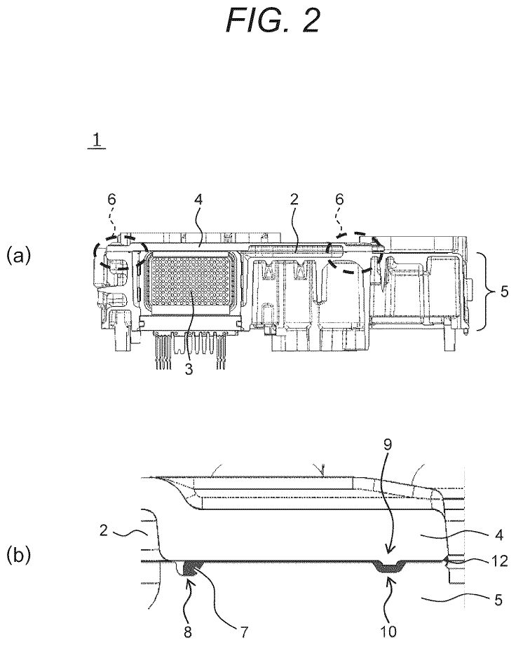

### FIG. 2

FIG. 2(a) is a cross-sectional view taken along line A-A of FIG. 1(b), and FIG. 2(b) is an enlarged view of a housing connection portion of FIG. 2(a). The semiconductor device 1 includes the power module 3, and the lower cover 4 is attached to the case 5 so that the power module 3 is housed in the case 5. As a result, a refrigerant channel 2 for cooling the power module 3 is formed. Hereinafter, the lower cover 4 will be described as the first housing 4, and the case 5 as a second housing 5.

In a housing connection portion 6, a seal material 7 is used on the adhesion surfaces when the first housing 4 and the second housing 5 adhere to each other on the adhesion surfaces to form the refrigerant channel 2. The seal material 7 is, for example, a silicone-based adhesive, and causes the adhesion surfaces of the first housing 4 and the second housing 5 to adhere to each other and seals them. In the housing connection portion 6, by connecting the first housing 4 and the second housing 5, two grooves are formed at the connection portion as a groove by a seal material pressing portion 9 and a seal material application portion 10 and as a groove by the seal material pressing portion 9 and a seal material inflow suppression portion 8. In these two grooves, the groove located on the outer peripheral portion of the first housing 4 and the second housing 5 is formed by the seal material pressing portion 9 in the first housing 4 and the seal material application portion 10 in the second housing 5.

The seal material application portion 10 has a recessed shape, and the seal material pressing portion 9 has a protruded shape having a protrusion. The seal material application portion 10 and the seal material pressing portion 9 adhere to each other to surround the refrigerant channel 2. Note that the seal material application portion 10 may have a trapezoidal shape in consideration of easy flow of the seal material 7.

On the other hand, one of the adhesion surfaces of the first housing 4 and the second housing 5 has the groove formed at a position closer to the refrigerant channel 2 than the seal material application portion 10, and as this groove, the second housing 5 has the seal material inflow suppression portion 8 of a recessed shape. The seal material inflow suppression portion 8 is formed to surround the refrigerant channel 2. Further, a seal material storage portion 12 is provided outside the refrigerant channel 2 of the first housing 4 and the second housing 5.

Note that the seal material application portion 10 is not limited to the form illustrated in FIG. 2, and is formed on one of the adhesion surfaces of the first housing 4 or the second housing 5, and the seal material 7 is applied thereto. In this case, the seal material pressing portion 9 is formed at a position corresponding to the seal material application portion 10 on the other adhesion surface, and presses the seal material 7 disposed on the seal material application portion 10.

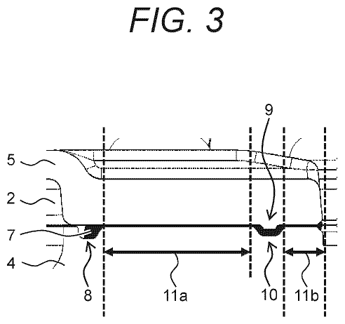

### FIG. 3

The seal material application portion 10 and the seal material inflow suppression portion 8 are disposed to control the spread of the seal material 7 at a time of adhesion between the first housing 4 and the second housing 5. The seal material application portion 10 is disposed at a position closer to the outer peripheral portion than the refrigerant channel 2 on the adhesion surfaces of the first housing 4 and the second housing 5. On the other hand, the seal material inflow suppression portion 8 is disposed at a position closer to the refrigerant channel 2 than the outer peripheral portion on the adhesion surfaces of the first housing 4 and the second housing 5.

On the adhesion surfaces, in a case where a length from the position of the seal material application portion 10 to the position of the seal material inflow suppression portion 8 is defined as a first length 11a, and a length from the outer peripheral portion of the adhesion surface to the position of the seal material application portion 10 is defined as a second length 11b, the first length 11a is longer than the second length 11b. That is, with respect to the seal material application portion 10, the adhesion surface closer to the refrigerant channel 2 has a greater area than the outer peripheral portion of the adhesion surface has. This is because an internal pressure is applied to the adhesion surface from the refrigerant in the refrigerant channel 2, and thus the first housing 4 expands due to the internal pressure. At this time, since a load due to the internal pressure needs to be efficiently transmitted to the seal material 7, a portion (first length 11a) having the greater adhesion area is provided to be close to the refrigerant channel 2. In addition, since the seal material 7 extrudes into the seal material inflow suppression portion 8 at the time of the adhesion of the housings, the adhesion surface of a wide range is secured on the first length 11a for preventing the seal material 7 from extruding excessively.

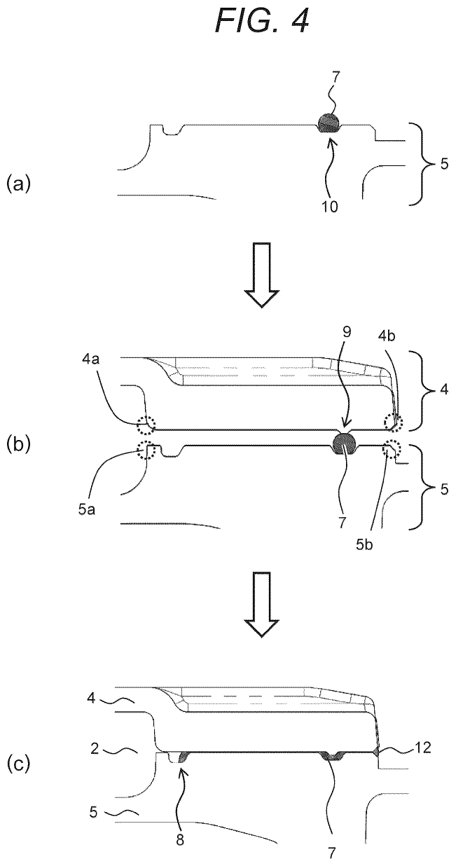

### FIG. 4

FIG. 4(a) is a view in which the seal material 7 is applied to the seal material application portion 10, FIG. 4(b) is a view illustrating a state in the middle of the adhesion between the first housing 4 and the second housing 5, and FIG. 4(c) is a view illustrating a state in which the first housing 4 and the second housing 5 adhere to each other. FIG. 4(a) to 4(c) illustrate a series of processes for connecting the housings.

First, the seal material 7 is applied to the seal material application portion 10 of the second housing 5. The application amount of the seal material 7 is controlled to a predetermined application amount by a dispenser or the like, that is, the application amount is adjusted so that the seal material 7 that is pushed to spread in the right-and-left direction during the adhesion of the housings is retained in the seal material inflow suppression portion 8. Therefore, the inflow of the seal material into the refrigerant channel 2 can be suppressed. Further, the seal material application portion 10 has an enough width for receiving the seal material 7.

Subsequently, in the process of attaching the first housing 4 to the second housing 5, the seal material pressing portion 9 of the first housing 4 comes into contact with the seal material 7 applied to the seal material application portion 10 and starts to press the seal material 7. At the time of the adhesion of the first housing 4 and the second housing 5, the seal material pressing portion 9 crushes to spread the seal material 7 while digging into the seal material 7. Note that, since the seal material application portion 10 having a recessed shape and the seal material pressing portion 9 having a protruded shape have adhesion areas equivalent to each other and have no adhesion difference, the seal material 7 can provide a sufficient adhesive force for preventing the peeling at an interface.

When the first housing 4 is assembled to the second housing 5, the seal material 7 is pushed to spread in the right-and-left direction of the adhesion surfaces. As a result, a part of the seal material 7 is stored in the groove of the seal material inflow suppression portion 8 on the side of the refrigerant channel 2, while a part of the seal material 7 is stored in the seal material storage portion 12 when the seal material 7 is pushed to spread toward the outer peripheral portion.

Since the process of the adhesion of the housings is performed using such a configuration, the seal material pressing portion 9 of the first housing 4 separates air caught in the seal material 7 discharges the air toward both the ends of the adhesion surfaces, and thus the adhesion area in the seal material application portion 10 can be secured. In addition, uniformization of the adhesive strength makes the adhesive strength of the adhesion surfaces stable. Further, since the seal material 7 is applied and pressed in only one groove instead of the double groove structure described as the conventional technique, adhesion reliability can be improved by preventing air entrainment.

On the adhesion surfaces of the housings, an end portion of the first housing 4 on the side of the refrigerant channel 2 is defined as a first end portion 4a, an end portion of the first housing 4 on the side of the outer peripheral is defined as a second end portion 4b, an end portion of the second housing 5 on the side of the refrigerant channel 2 is defined as a third end portion 5a, and an end portion of the second housing 5 on the side of the outer peripheral is defined as a fourth end portion 5b. The first housing 4 and the second housing 5 adhere to each other with the first end portion 4a and the third end portion 5a being in contact with each other and the second end portion 4b and the fourth end portion 5b being in contact with each other.

When the housings overlap each other, the seal material 7 has a property of easily adhering to the housing having a surface of a greater area, and thus a problem of the reliability of the adhesion surface comes up. This problem can be prevented by adhering the first housing 4 and the second housing 5 with the lengths of their end portions being equal to each other. Further, since the first end portion 4a and the third end portion 5a are joined, there is an effect that the seal material 7 does not flow into the refrigerant channel 2 even if the seal material 7 is separated from the seal material inflow suppression portion 8.

Further, the first housing 4 and the second housing 5 are provided with the seal material storage portion 12, in which the seal material 7 is stored, on the outer peripheral portion of the adhesion surfaces of the housings. As a result, the seal material 7 can be prevented from excessively extruding to the outer peripheral portion of the adhesion surfaces, and thus corrosion of the seal material 7 can be reduced by preventing salt storage in the extruded portion.

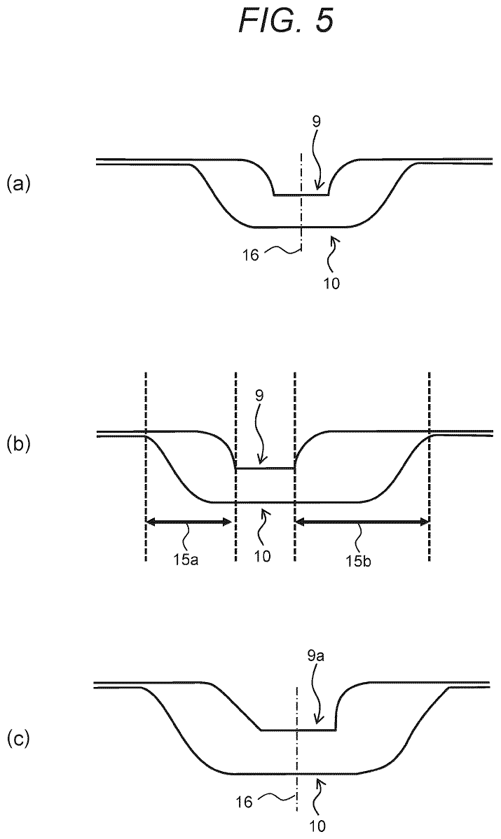

### FIG. 5

The seal material application portion 10 has both the ends with a slope shape instead of a right-angled shape so that the seal material pressing portion 9 can discharge air while pushing to spread the seal material 7 when the seal material 7 is applied and the first housing 4 is attached to the second housing 5. This makes the flowing of the seal material 7 easy at the time of the adhesion of the housings. Since the seal material pressing portion 9 is the center of the leftward and rightward spread of the seal material 7 during the assembly, the spread of the seal material 7 can be controlled by the position and shape of the pressing portion 9.

At least one of the seal material pressing portion 9 and the seal material application portion 10 of the first housing 4 may have a trapezoidal shape. FIG. 5(a) illustrates an example in which the seal material pressing portion 9 has a trapezoidal shape. In FIG. 5(a), the seal material pressing portion 9 and the seal material application portion 10 are located symmetrically with respect to a center line 16.

Further, the seal material pressing portion 9 may have a symmetrical shape or an asymmetrical shape. Specifically, as illustrated in FIG. 5(b), the seal material pressing portion 9 may be located so that, with respect to the width of the seal material application portion 10, the length 15a of the groove from the seal material pressing portion 9 to one end portion of the seal material application portion 10 is different from the length 15b of the groove from the seal material pressing portion 9 to the other end portion of the seal material application portion 10. In addition, as illustrated in FIG. 5(c), the seal material pressing portion 9 may be a seal material pressing portion 9a that is asymmetric with respect to the center line 16.

Although the trapezoidal shape of the seal material pressing portion 9 has been described as a pattern example, the seal material pressing portion 9 may have other shapes as long as it can presses the seal material 7 and secure the adhesion reliability at the adhesion surfaces of the housings.

### First to Fourth Modifications

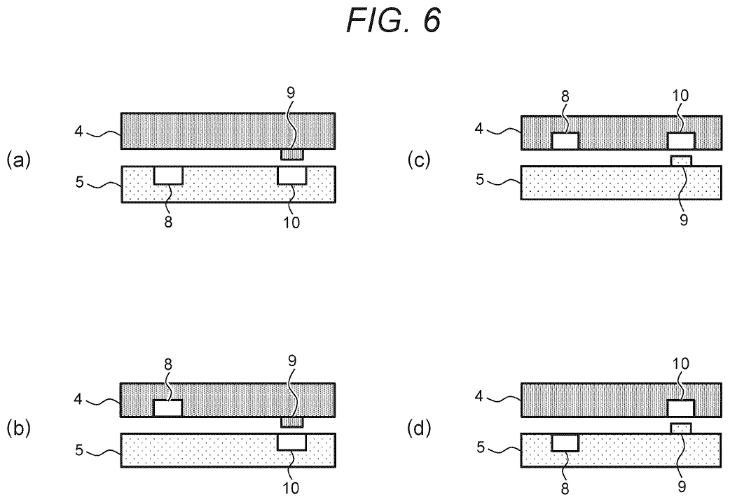

### FIG. 6

The seal material inflow suppression portion 8 may be provided in either the first housing 4 or the second housing 5. In addition, the seal material pressing portion 9 and the seal material application portion 10 can be provided without depending on which of the first housing 4 and the second housing 5 has the seal material inflow suppression portion 8 as long as the seal material pressing portion 9 is housed in the seal material application portion 10 at the time of the adhesion.

FIG. 6(a) illustrates an example in which the seal material inflow suppression portion 8 and the seal material application portion 10 are disposed in the second housing 5, and the seal material pressing portion 9 is disposed in the first housing 4. FIG. 6(b) illustrates an example in which the seal material inflow suppression portion 8 and the seal material pressing portion 9 are disposed in the first housing 4, and the seal material application portion 10 is disposed in the second housing 5. FIG. 6(c) illustrates an example in which the seal material inflow suppression portion 8 and the seal material application portion 10 are disposed in the first housing 4, and the seal material pressing portion 9 is disposed in the second housing 5. FIG. 6(d) illustrates an example in which the seal material application portion 10 is disposed in the first housing 4, and the seal material inflow suppression portion 8 and the seal material pressing portion 9 are disposed in the second housing 5.

### Fifth Modification and Sixth Modification

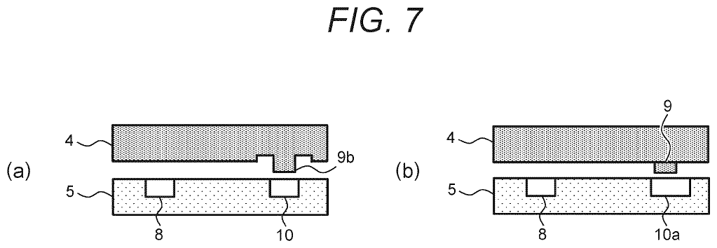

### FIG. 7

As illustrated in FIG. 7(a), the same effect can be produced by the seal material pressing portion 9b having a groove around the pressing portion, and thus the seal material pressing portion 9 can be formed by simpler processing than the seal material pressing portion 9 having no groove. Further, as illustrated in FIG. 7(b), the seal material application portion 10 may not have an adhesion area corresponding to the seal material pressing portion 9, and may have a shape such that the seal material pressing portion 9 is at the center of the seal material application portion 10.

According to one embodiment of the present invention described above, the following operational effects are produced.
(1) The semiconductor device 1 includes the power module 3 that outputs electric power for driving a motor using a semiconductor, the first housing 4 and the second housing 5 respectively having adhesion surfaces, the adhesion surfaces adhering to each other to form the refrigerant channel 2 for cooling the power module 3, and the seal material 7 that seals the adhesion surfaces of the first housing 4 and the second housing 5. One of the adhesion surfaces of the first housing 4 and the second housing 5 includes the seal material application portion 10 to which the seal material 7 is applied, the other adhesion surface includes the seal material pressing portion 9 against which the seal material 7 is pressed, the seal material pressing portion 9 being provided at a position corresponding to the seal material application portion 10, one of the adhesion surfaces of the first housing 4 and the second housing 5 includes the seal material inflow suppression portion 8 that suppresses an inflow of the seal material 7 into the refrigerant channel 2, the seal material inflow suppression portion 8 being provided at a position closer to the refrigerant channel 2 than the seal material application portion 10. This makes it is possible to provide the semiconductor device 1 where prevention of decrease in adhesive strength is compatible with prevention of inflow of an adhesive into the refrigerant channel.
(2) The seal material application portion 10 has a recessed shape, the seal material pressing portion 9 has a protruded shape, and the seal material application portion 10 and the seal material pressing portion 9 adhere to surround the refrigerant channel 2. In this manner, the refrigerant channel 2 is formed by the housings having the stable adhesion surfaces.
(3) At least one of the seal material application portion 10 and the seal material pressing portion 9 has a trapezoidal shape. This makes the flowing of the seal material 7 easy.
(4) The seal material inflow suppression portion 8 has a recessed shape and is formed to surround the refrigerant channel 2. In this way, while the reliability of the adhesion surfaces is secured, the spread of the seal material 7 is controlled so that the seal material 7 does not flow into the refrigerant channel 2.
(5) On the adhesion surfaces, the length from the position of the seal material application portion 10 to the position of the seal material inflow suppression portion 8 is longer than the length from the outer peripheral portion of the adhesion surface to the position of the seal material application portion 10. As a result, a load due to an internal pressure from the refrigerant channel 2 can be efficiently transmitted to the seal material 7.
(6) The adhesion surface of first housing 4 includes the first end portion 4a that is an end portion on the side of the refrigerant channel 2 and the second end portion 4b that is an end portion on the side of the outer peripheral portion, the adhesion surface of the second housing 5 includes the third end portion 5a that is an end portion on the side of the refrigerant channel 2 and the fourth end portion 5b that is an end portion on the side of the outer peripheral portion, and the first housing 4 and the second housing 5 adhere to each other with the first end portion 4a and the third end portion 5a being in contact with each other and the second end portion 4b and the fourth end portion 5b being in contact with each other. This can prevent the seal material 7 from being mixed into the refrigerant channel 2.
(7) The first housing 4 and the second housing 5 each have the seal material storage portion 12, in which the seal material 7 is stored, on the outer peripheral portions of the adhesion surfaces of the housings. As a result, corrosion of the seal material 7 can be reduced by preventing salt accumulation from occurring in the protruding portion.

Note that the present invention is not limited to the above embodiment, and various modifications and other configurations can be combined without departing from the gist of the present invention. In addition, the present invention is not limited to one including entire the configuration described in the above embodiment, and includes one in which a part of the configuration is deleted.

### REFERENCE SIGNS LIST

1 semiconductor device
2 refrigerant channel
3 power module
4 lower cover (first housing)
4a first end portion
4b second end portion
5 case (second housing)
5a third end portion
5b fourth end portion
6 housing connection portion
7 seal material
8 seal material inflow suppression portion
9 seal material pressing portion
9a asymmetric pressing portion
9b pressing portion having groove on periphery
10 seal material application portion
10a application portion having large groove
11 length
11a first length
11b second length
12 seal material storage portion
13 power module plate
14 water passage pipe
15 length
15a length of first groove
15b length of second groove
16 center line

1. A semiconductor device comprising:
a power module that outputs electric power for driving a motor using a semiconductor;
a first housing and a second housing respectively having adhesion surfaces, the adhesion surfaces adhering to each other to provide a refrigerant channel for cooling the power module; and
a seal material that seals the adhesion surfaces of the first housing and the second housing,
wherein one of the adhesion surfaces of the first housing and the second housing includes a seal material application portion to which the seal material is applied,
the other adhesion surface includes a seal material pressing portion against which the seal material is pressed, the seal material pressing portion being provided at a position corresponding to the seal material application portion, and
one of the adhesion surfaces of the first housing and the second housing includes a seal material inflow suppression portion that suppresses an inflow of the seal material into the refrigerant channel, the seal material inflow suppression portion being provided at a position closer to the refrigerant channel than the seal material application portion.

2. The semiconductor device according to claim 1, wherein
the seal material application portion has a recessed shape,
the seal material pressing portion has a protruded shape, and
the seal material application portion and the seal material pressing portion adhere to each other to surround the refrigerant channel.

3. The semiconductor device according to claim 1, wherein at least one of the seal material application portion and the seal material pressing portion has a trapezoidal shape.

4. The semiconductor device according to claim 1, wherein the seal material inflow suppression portion has a recessed shape and is provided to surround the refrigerant channel.

5. The semiconductor device according to claim 1, wherein on the adhesion surfaces, a length from a position of the seal material application portion to a position of the seal material inflow suppression portion is longer than a length from an outer peripheral portion of the adhesion surface to the position of the seal material application portion.

6. The semiconductor device according to claim 1, wherein
the adhesion surface of the first housing includes a first end portion that is an end portion on the refrigerant channel side and a second end portion that is an end portion of the outer peripheral portion side,
the adhesion surface of the second housing includes a third end portion that is an end portion on the refrigerant channel side and a fourth end portion that is an end portion on the outer peripheral portion side, and
the first housing and the second housing adhere to each other with the first end portion and the third end portion being in contact with each other and the second end portion and the fourth end portion being in contact with each other.

7. The semiconductor device according to claim 1, wherein the first housing and the second housing each include a seal material storage portion, in which the seal material is stored, on the outer peripheral portions of the adhesion surfaces of the first and second housings.
